(19) United States
(12) Patent Application Publication
(10) Pub. No.: US 2025/0199032 A1
(43) Pub. Date: Jun. 19, 2025

(54) METAL MOLDED ARTICLE, MANUFACTURING METHOD THEREFOR, AND INSPECTION DEVICE HAVING SAME

(71) Applicant: POINT ENGINEERING CO., LTD., Chungcheongnam-do (KR)

(72) Inventors: Bum Mo AHN, Gyeonggi-do (KR); Seung Ho PARK, Gyeonggi-do (KR); Sung Hyun BYUN, Gyeonggi-do (KR)

(73) Assignee: POINT ENGINEERING CO., LTD., Chungcheongnam-do (KR)

(21) Appl. No.: 18/845,867

(22) PCT Filed: Mar. 7, 2023
(86) PCT No.: PCT/KR2023/003128

§ 371 Date: Sep. 10, 2024

(30) Foreign Application Priority Data
Mar. 11, 2022 (KR) 10-2022-0030551

(51) Int. Cl. G01R 1/067; G01R 3/00

(52) U.S. Cl. CPC G01R 1/06755; G01R 1/06716; G01R 1/06733; G01R 3/00

(57) ABSTRACT

The present invention provides a metal molded article, a manufacturing method therefor, and an inspection device having same. The metal molded article has an overall length dimension in a longitudinal direction, an overall thickness dimension in a thickness direction perpendicular to the longitudinal direction, and an overall width dimension in a width direction perpendicular to the longitudinal direction. The metal molded article is divided into a first body region and a second body region in the thickness direction. The lateral surfaces of the first body region are provided with multiple micro-trenches that are grooves formed to be elongated in the thickness direction and arranged side by side all over the entire lateral surfaces of the first body region. The lateral surfaces of the second body region are not provided with these micro-trenches.

### TECHNICAL FIELD

The present disclosure relates to a metal molded article, a manufacturing method thereof. and an inspection device equipped with the same metal molded article.

### BACKGROUND ART

A metal molded article may be manufactured using MEMS and plating techniques, and its application areas may vary depending on its purpose. For example, a metal molded article may be an electrically conductive contact pin to inspect an inspection target. The background art of the present disclosure will be described with reference to an example in which the metal molded article is an electrically conductive contact pin.

To test the electrical characteristics of a semiconductor device, an inspection target (semiconductor wafer or semiconductor package) is moved to a test device equipped with a plurality of electrically conductive contact pins, and the electrically conductive contact pins are brought into contact with respective external terminals (solder balls or bumps) provided on the inspection target. The inspection device includes but is not limited to, a probe card or a test socket.

A wafer-level inspection for semiconductor devices is performed with the use of a probe card. The probe card is mounted between a wafer and the head of a tester and acts as a mediator by enabling 8,000 to 100,000 electrically conductive contact pins on the probe card to be in contact with pads within individual chips on the wafer so that test signals can be communicated between a probe tester and each of individual chips. There are various types of probe cards: a vertical probe card, a cantilever probe card, and a MEMS probe card. The electrically conductive contact pins used in the vertical probe card may be pre-deformed when manufactured. Alternatively, the electrically conductive contact pins initially may have a straight structure when manufactured and may be deformed later by shifting a guide plate in a lateral direction. The different structures of the electrically conductive contact pins have been adopted and used. Recently, with the advancement and increased integration of semiconductor technology, the pitch of external terminals in an inspection target is increasingly decreasing. Conventional electrically conductive contact pins are structured in a manner that their body bulges when pressed from the opposite ends thereof and is finally elastically bent or curved sideways direction. When the narrow-pitched conductive contact pins are deformed, some of the contact pins may come into contact with neighboring contact pins, often resulting in a short-circuit.

Meanwhile, a package-level inspection for semiconductor devices is performed with a test socket. The conventional test sockets include a pogo-type test socket and a rubber-type test socket.

The electrically conductive contact pins (hereinafter referred to as “pogo-type socket pins”) used in the pogo-type test socket is composed of a pin portion and a pin-accommodating barrel. The pin portion provides necessary contact pressure and absorbs shock at the contact position because a spring member is provided between the pin portion and each of the plungers installed at respective ends of the pin portion. In order for the pin portion to slide within the barrel, there is required to be a clearance between the outer surface of the pin portion and the inner surface of the barrel. However, it is difficult to precisely control the clearance between the outer surface of the pin portion and the inner surface of the barrel because the barrels and the pin portions are separately manufactured and then combined for the production of pogo-type socket pins. Therefore, loss and distortion of electrical signals occur in a process in which signals are transmitted to the barrel via the plungers disposed at the respective ends of the pin portion, causing unstable contact. In addition, the pin portion has a sharp tip to increase the contact effect with an external terminal of an inspection target. The sharp tip leaves traces of press-fitting or dents on the surface of the external terminal of the inspection target after inspection. A contact shape loss of the external terminals leads to errors in vision inspection and the reliability deterioration of the external terminals in subsequent processes such as soldering.

Meanwhile, electrically conductive contact pins (hereinafter, referred to as “rubber-type socket pins”) used in a rubber-type test socket have a structure in which conductive micro-balls are placed inside silicone rubber, which is a rubber material. The structure is such that when a target to be inspected (for example, a semiconductor package) is placed thereon, and a socket is closed to generate stress, the gold-based conductive micro-balls are strongly pressed against each other, thereby increasing the conductivity and making an electrical connection. However, these rubber-type socket pins are required to be pressed with extremely strong pressure to ensure contact stability.

Meanwhile, the conventional rubber-type socket pins are manufactured by preparing a molding material, which is a material with conductive particles dispersed in a fluid elastic material, inserting the molding material into a predetermined mold, and applying a magnetic field in the thickness direction to have the conductive particles arranged in the thickness direction. Therefore, the conductive particles become irregularly arranged when the gap between magnetic fields narrows, the signal flows in the plane direction. Therefore, there are limitations in responding to the narrow pitch technique trend with the conventional rubber-type socket pins. In addition, the pogo-type socket pins have a problem that the pogo-type socket pins cannot be manufactured into a compact size because the barrel and pin portion are initially separately manufactured and then combined later for use thereof. Therefore, there are also limitations in responding to the narrow pitch technique trend with the conventional pogo-type socket pins.

Therefore, there is a need to develop a new type of electrically conductive contact pins and a new inspection device equipped with the same that can improve inspection reliability for inspection targets to keep up with recent technological trends.

In manufacturing metal molded articles such as electrically conductive contact pins, a MEMS process may be used. The process of manufacturing electrically conductive contact pins using the MEMS process involves: first, applying a photoresist film to the surface of a conductive substrate and patterning the photoresist film; and second, depositing a metal material by electroplating on the exposed surface of the conductive substrate through an opening, by using the photoresist film as a mold, and removing the photoresist film and conductive substrate to obtain contact pins. In this way, electrically conductive contact pins manufactured using the MEMS process are hereinafter referred to as “MEMS contact pins”. The MEMS contact pins have the same shape as the opening formed in the mold of the photoresist film. In this case, the thickness of the MEMS contact pins is affected by the height of the mold of the photoresist film.

When the photoresist film is used as a mold for the electroplating method, it is difficult to increase the mold height sufficiently with only a single-layered photoresist film. Therefore, the thickness of the MEMS contact pins m may be sufficient. Considering electrical conductivity, resilience, and brittle fracture, the MEMS contact pins need to have a sufficient thickness. To increase the thickness of the MEMS contact pins, a mold of a multi-layered photoresist film may be considered. However, in this case, the photoresist film may have fine steps in the layered structure, which may result in that the lateral surfaces of the MEMS contact pin are not perpendicularly, and slightly stepped areas remain. In addition, when the photoresist film is multi-layered, it is difficult to precisely reproduce the shape of MEMS contact pins with a dimension range of several tens of um or less.

### RELATED ART DOCUMENT

### Patent Document

(Patent Document 1) Korean Patent Application Publication No. 10-2018-0004753

### DETAILED DESCRIPTION OF THE DISCLOSURE

### Technical Problem

To address the problems described above, an objective of the present disclosure is to provide a metal molded article that has a highly flexible and reliable shape, to provide a manufacturing method thereof, and to provide an inspection device equipped with the same metal molded article.

Another objective of the present disclosure is to provide a metal molded article that improves inspection reliability for inspection targets, to provide a manufacturing method thereof, and to provide an inspection device equipped with the same metal molded article.

A further objective of the present disclosure is to provide a metal molded article manufactured using a MEMS process, the metal molded article having a sufficient thickness not to easily buckle in in undesired directions, and a manufacturing method of the metal molded article and an inspection device equipped with the metal molded article are also provided.

### Technical Solution

To achieve these objectives, the present disclosure provided a metal molded article having an overall length dimension L in a longitudinal direction (±y direction), an overall thickness dimension H in a thickness direction (±z direction) perpendicular to the longitudinal direction, and an overall width dimension W in a width direction (±x direction) perpendicular to the longitudinal direction. The metal molded article is divided into a first body region and a second body region in the thickness direction. Lateral surfaces of the first body region are provided with multiple micro-trenches that are grooves formed to be elongated in the thickness direction and arranged side by side all over the lateral surfaces, and lateral surfaces of the second body region are not provided with micro-trenches.

In addition, the metal molded article has a first surface and a second surface opposite the first surface, and the lateral surfaces of the metal molded article are surfaces connecting the first surface and the second surface to each other. The micro-trenches are not formed on the first surface and the second surface.

In addition, the micro-trenches have a depth of 20 nm or more and 1 μm or less.

In addition, a portion of the second body region has a protrusion that protrudes beyond the first body region. The second body region, excluding the protrusion, has the same shape as the first body region.

In addition, the first body region has a thickness greater than that of the second body region.

In addition, the metal molded article is an electrically conductive contact pin connected to an inspection target to inspect electrical characteristics of the inspection target.

In addition, the metal molded article includes: a first connection portion connected to a circuit wiring portion; a second connection portion connected to an inspection target; and an elastic portion that allows the first connection portion to be elastically displaced relative to the second connection portion in the longitudinal direction. The second connection portion include a protrusion formed such that a portion of the second body region protrudes beyond the first body region.

In addition, the metal molded article may include an outer wall portion provided outside the elastic portion and arranged to extend in the longitudinal direction of the electrically conductive contact pin to allow the elastic portion to contract and extend in the longitudinal direction of the electrically conductive pin and to prevent the elastic portion from buckling while the elastic portion contracts.

In addition, the metal molded article includes: a first connection portion connected to a circuit wiring portion; a second connection portion connected to an inspection target; an upper elastic portion connected to the first connection portion; a lower elastic portion connected to the second connection portion; and an inelastic portion connected to the upper elastic portion and the lower elastic portion and interposed between the upper elastic portion and the lower elastic portion, in which the second connection portion includes a protrusion formed such that a portion of the second body region protrudes beyond the first body region in the second body region.

In addition, the metal molded article includes: an upper outer wall portion provided outside the upper elastic portion; and a lower outer wall portion provided outside the lower elastic portion.

In addition, the upper outer wall portion includes a latching portion that protrudes to prevent the metal molded article from being separated from a guide plate.

Meanwhile, an inspection device of the present disclosure includes: a metal molded article: a guide plate into which the metal molded article is inserted and installed; and a circuit wiring portion electrically connected to one side of the metal molded article. The metal molded article includes: a first body portion provided with multiple micro-trenches that are grooves formed to be elongated in the thickness direction and arranged side by side over the entire lateral surfaces of the first body region; and a second body portion formed to be continuous to the first body region in the thickness direction and provided with no micro-trenches on lateral surfaces thereof.

In addition, the metal molded article includes: a first connection portion connected to the circuit wiring portion; a second connection portion connected to an inspection target; and an elastic portion that allows the first connection portion to be elastically displaced relative to the second connection portion in the longitudinal direction, the second connection portion including a protrusion formed such that a portion of the second body region protrudes beyond the first body region.

Meanwhile, a method of manufacturing a metal molded article according to the present disclosure includes: forming a lower seed layer on a lower surface of an anodized film; forming a patternable material on an upper surface of the anodized film; forming a second opening to expose the upper surface of the anodized film by patterning the patternable material: forming a first opening by wet-etching the anodized film to expose the lower seed layer through the second opening: forming a body metal layer in the first opening and the second opening through plating: and extracting the body metal layer by removing the lower seed layer, the patternable material, and the anodized film.

In addition, the patternable material may be a photoresist.

In addition, the method may further include forming an upper seed layer on the upper surface of the anodized film before forming the first opening.

### Advantageous Effects

The present disclosure provides a metal molded article that has a highly flexible and reliable shape, provides a manufacturing method thereof, and provides an inspection device equipped with the same metal molded article.

In addition, the present disclosure provides a metal molded article that improves inspection reliability for inspection targets, provides a manufacturing method thereof, and provides an inspection device equipped with the same metal molded article.

In addition, the present disclosure provides a sufficiently thick metal molded article manufactured using a MEMS process not to easily buckle in undesired directions, and also the present disclosure provides a manufacturing method thereof and an inspection device equipped with the same metal molded article.

### DESCRIPTION OF DRAWINGS

FIG. 1 illustrates a plan view of a metal molded article according to a preferred embodiment of the present disclosure;

FIG. 2 illustrates an enlarged view of part A of FIG. 1;

FIG. 3 illustrates an enlarged view of part B of FIG. 1;

FIG. 4 illustrates an enlarged view of part C of FIG. 1;

FIG. 5 illustrates a perspective view of a metal molded article according to another preferred embodiment of the present disclosure;

FIG. 6 illustrates a partial perspective view of a metal molded article according to a further preferred embodiment of the present disclosure;

FIG. 7 illustrates an enlarged view of part B of FIG. 6;

FIGS. 8 to 10 illustrate photographs of a metal molded article according to a yet further preferred embodiment of the present disclosure;

FIGS. 11a to 11e show views illustrating a method of manufacturing a metal molded article according to a still yet further preferred embodiment of the present disclosure;

FIG. 12 illustrates a view of an inspection device equipped with metal molded articles according to a still yet further preferred embodiment of the present disclosure; and

FIG. 13 illustrates an enlarged view of the part of FIG. 12.

### MODE FOR DISCLOSURE

The following merely describes the principles of the present disclosure. Accordingly, those skilled in the art will be able to invent various devices that embody the principles of the present disclosure and fall within the concept and scope of the present disclosure, although not clearly described or shown herein. In addition, all conditional terms and embodiments listed herein are, in principle, expressly intended solely to ensure that the inventive concept can be understood. All conditional terms and embodiments listed should be understood as non-limiting to the specifically listed embodiments and conditions.

The described objectives, features, and advantages will become clearer through the following detailed description in conjunction with the accompanying drawings. Accordingly, those skilled in the art to which the present disclosure pertains will be able to easily implement the technical idea of the present disclosure.

The embodiments described in this present disclosure will be described with reference to cross-sectional views and/or perspective views, which are ideal illustrations of the present disclosure. The thicknesses of films and regions shown in these drawings are exaggerated for effective explanation of technical content. The form of the illustration may be modified depending on manufacturing techniques and/or tolerance. In addition, the number of molded products shown in the drawings is only a partial number as an example. Accordingly, embodiments of the present disclosure are not limited to the specific form shown but also include changes in form produced according to the manufacturing process.

The metal molded article according to a preferred embodiment of the present disclosure refers to an object made from a metal with a predetermined thickness, height, and length. The metal molded article according to another preferred embodiment of the present disclosure may be manufactured using MEMS and plating techniques, and its application areas may vary depending on its purpose.

The metal molded article according to a further preferred embodiment of the present disclosure may be an electrically conductive contact pin to inspect an inspection target. The metal molded article is installed in an inspection device and used to transmit an electrical signal by electrically and physically contacting an inspection target. The inspection device may be an inspection device used in the semiconductor manufacturing process. For example, the inspection device may be a probe card or a test socket depending on the inspection target. The inspection device according to a yet further preferred embodiment of the present disclosure is not limited thereto. The inspection device includes any device that applies electricity to check whether the inspection target is defective.

Hereinafter, preferred embodiments of the present disclosure will be described in detail with reference to the drawings.

### Metal Molded Article (100)

Herein below, a metal molded article 100 according to a preferred embodiment of the present disclosure will first be described.

The width direction of the metal molded article 100 described below is the ±x direction indicated in the drawing. The longitudinal direction of the metal molded article 100 is the ±y direction indicated in the drawing. The thickness direction of the metal molded article 100 is the ±z direction indicated in the drawing.

The metal molded article 100 has an overall length dimension L in the longitudinal direction (±y direction). The metal molded article 100 has a total thickness dimension H in the thickness direction (±z direction) perpendicular to the longitudinal direction. The metal molded article 100 has an overall width dimension W in the width direction (±x direction) perpendicular to the longitudinal direction.

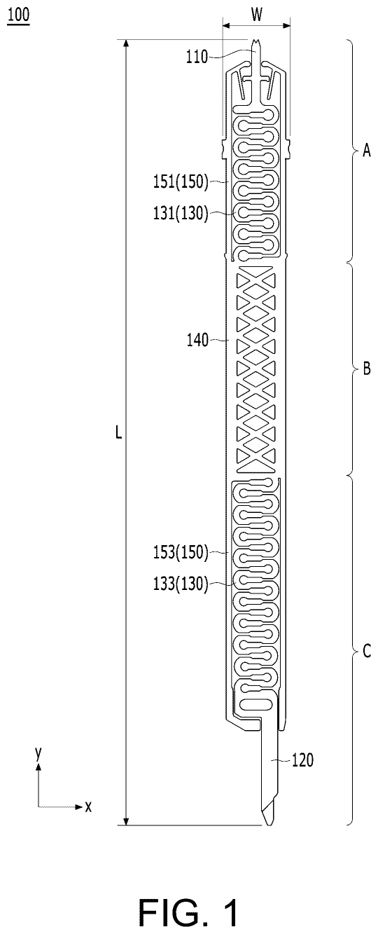

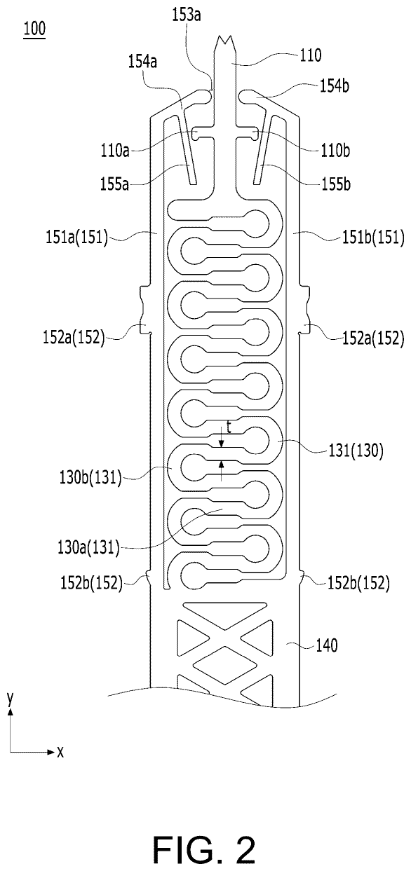

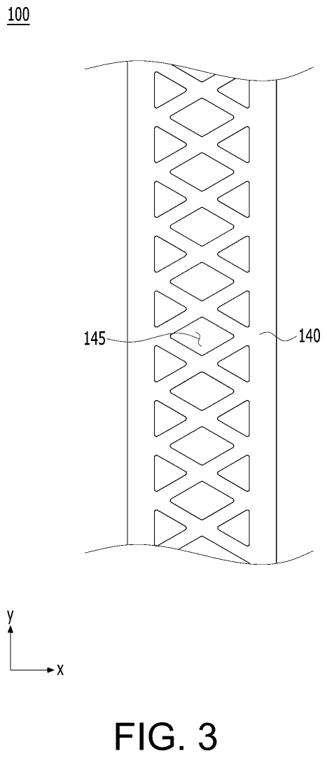

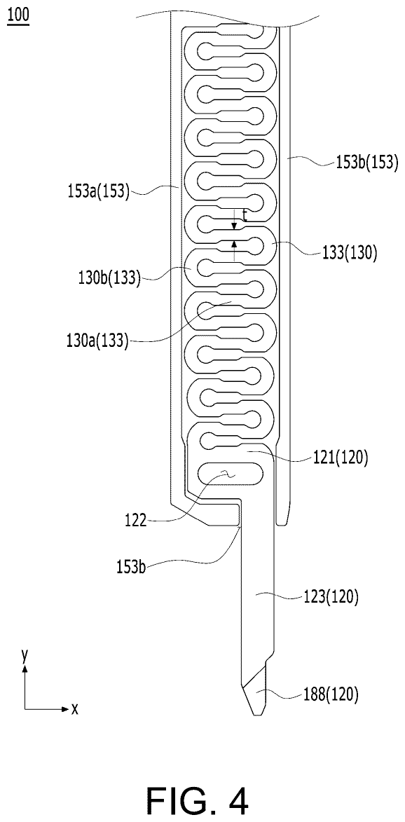

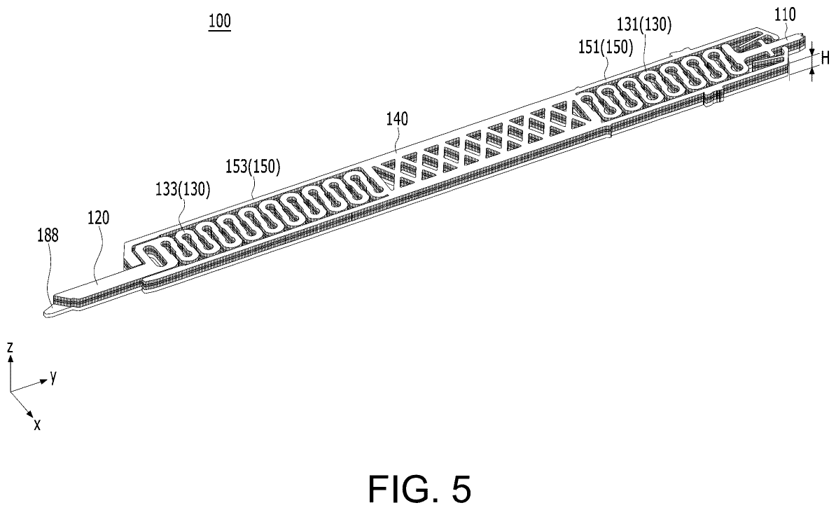

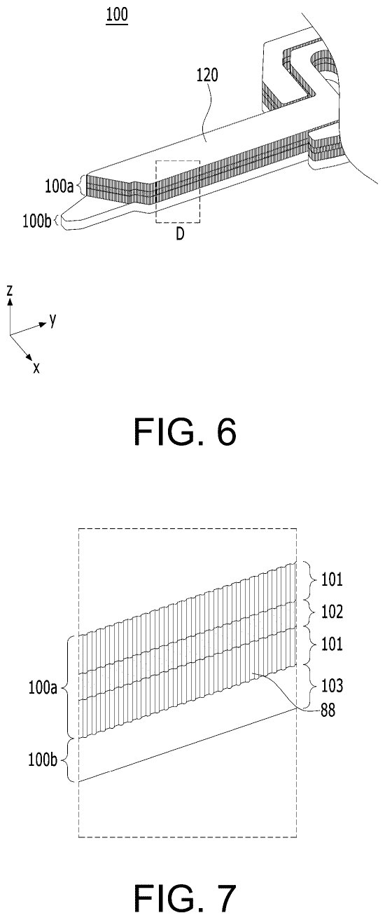

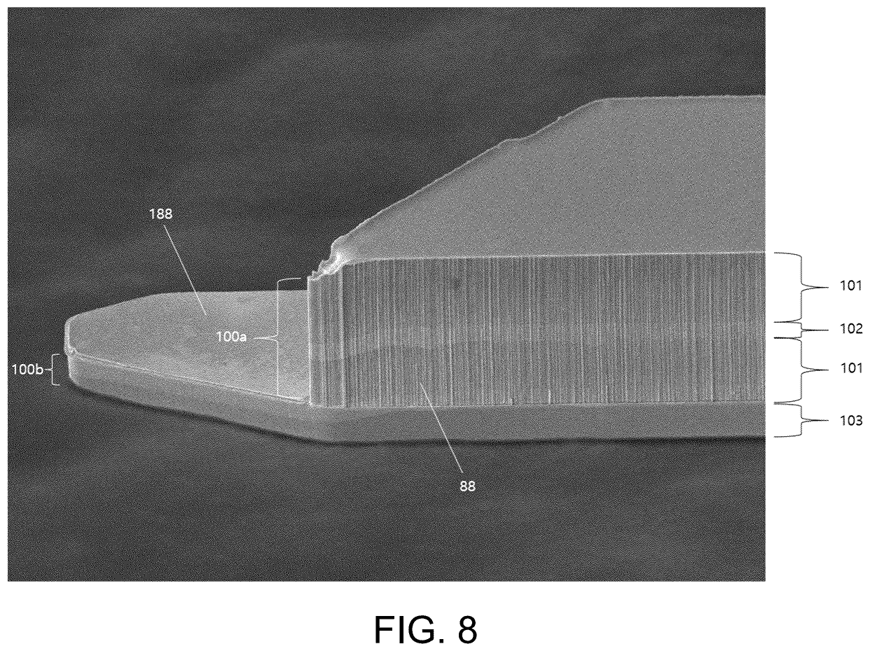

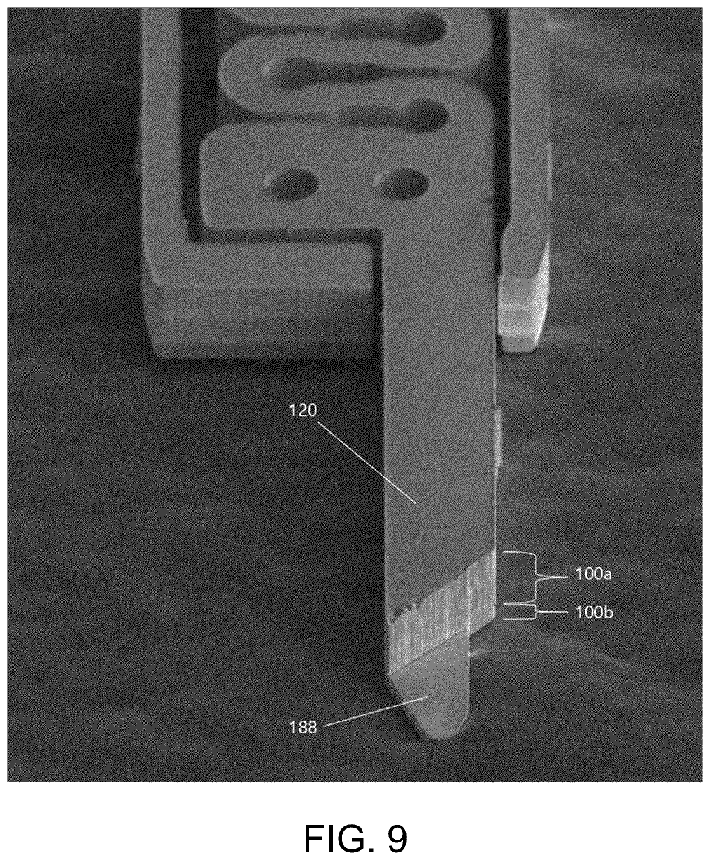

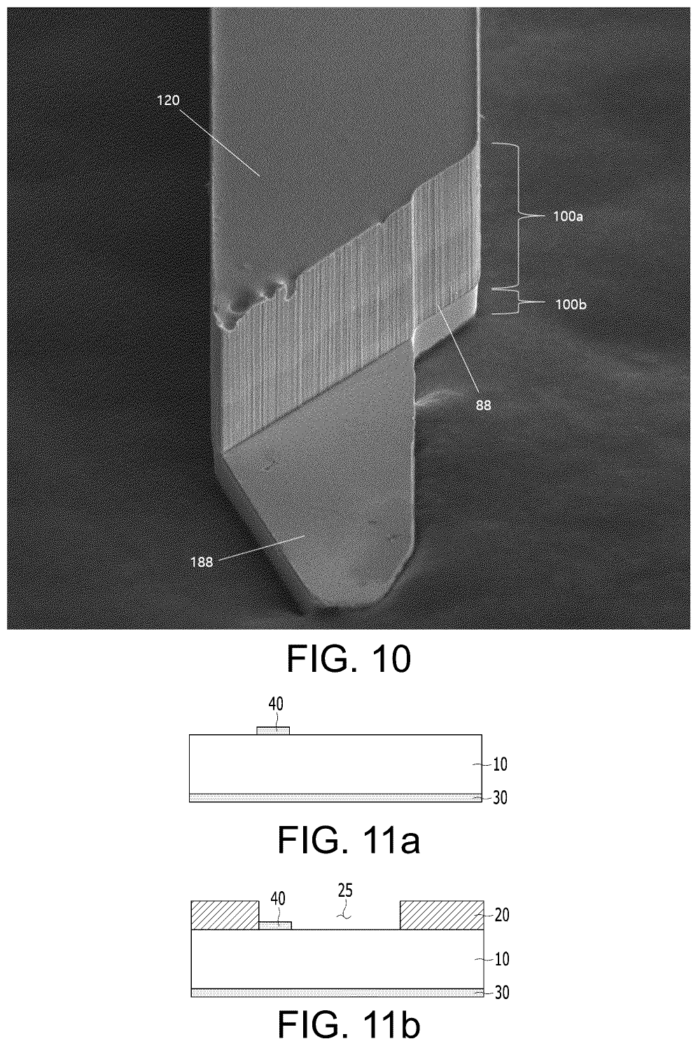

FIG. 1 shows a plan view of a metal molded article according to another preferred embodiment of the present disclosure. FIG. 2 shows an enlarged view of part A of FIG. 1. FIG. 3 shows an enlarged view of part B of FIG. 1. FIG. 4 shows an enlarged view of part C of FIG. 1. FIG. 5 shows a perspective view of a metal molded article according to a further preferred embodiment of the present disclosure. FIG. 6 shows a partial perspective view of a metal molded article according to a yet further preferred embodiment of the present disclosure. FIG. 7 shows an enlarged view of part B of FIG. 6. FIGS. 8 to 10 show photographs of a metal molded article according to a still yet further preferred embodiment of the present disclosure.

The metal molded article 100 has a first surface and a second surface opposite the first surface, and lateral surfaces are surfaces that connect the first surface and the second surface to each other. Thus, the metal molded article 100 is made of the first surface, second surface, and lateral surfaces.

First, referring to FIGS. 6 to 10, the metal molded article 100 is divided into a first body region 100a and a second body region 100b in the thickness direction (±z direction). Based on

FIG. 6, the first body region 100a is located at the upper position, and the second body region 100b is located below the first body region 100a. The metal molded article 100 is formed as an integrated body in which the first body region 100a and the second body region 100b are stacked to be continuous in the thickness direction (±z direction).

In the method of manufacturing the metal molded article 100 described later, the first body region 100a is defined by a mold portion of an anodized film 10, and the second body region 100b is defined by a mold portion of a patternable material 20. The first body region 100a and the second body region 100b differ depending on whether or not micro-trenches 88 are provided. That is, the first body region 100a and the second body region 100b differ depending on whether or not micro-trenches 88 are provided on the lateral surfaces thereof. The first body region 100a has the micro-trenches 88 on the lateral surfaces thereof. The second body region 100b does not have the micro-trenches 88 on the lateral surfaces thereof.

The first body region 100a of the metal molded article 100 includes multiple micro-trenches 88 on the lateral surfaces thereof. The multiple micro-trenches 88 are grooves formed to be elongated in the thickness direction (±z direction) of the metal molded article 100 and arranged side by side in a perpendicular direction to the thickness direction (±z direction) all over the entire lateral surfaces of the first body region 100a. Herein, the thickness direction (±z direction) of the metal molded article 100 refers to the direction in which a metal fill grows during electroplating.

Unlike the first body region 100a, there are no micro-trenches 88 on the lateral surfaces of the second body region 100b. At the end of the metal molded article 100, a portion of the second body region 100b protrudes beyond the first body region 100a to form a protrusion 188. Since the protrusion 188 is a portion of the second body region 100b, there are no micro-trenches 88 on the lateral surfaces of the protrusion 188. The second body region 100b, excluding the protrusion 188, has the same shape as the first body region 100a. That is, the first body region 100a and the second body region 100b have the same shape except for the protrusion 188. The protrusion 188 may be formed on at least a portion of the entire lateral surface of the metal molded article 100. When the protrusion 188 is formed on an end of the lateral surface of the metal molded article 100 that is in contact with an inspection target 400 or a circuit wiring portion 300, the protrusion 188 may function as a contact tip. In an embodiment of the present disclosure, the protrusion 188 is provided at an end of a second connection portion 120 and is used as a contact tip that comes into contact with an inspection target 400.

The micro-trenches 88 have a depth in a range of 20 nm to 1 μm and also a width in a range of 20 nm to 1 μm. Herein, the micro-trenches 88 originate in pores formed during the mold manufacturing of the anodized film 10. Accordingly, the micro-trenches 88 have a width and depth smaller than or equal to the diameter of the pores of the anodized film 10. Meanwhile, during the process of forming a first opening 15, which is an internal space in the anodized film 10, some of the pores in the anodized film 10 are crushed by an etching solution. Accordingly. at least some of the micro-trenches 88 may be formed with a depth greater than the diameter of the pores formed during anodization. The anodized film 10 includes numerous pores. At least a portion of the anodized film 10 is etched to form an internal space. A metal fill is formed inside the internal space by electroplating. Accordingly, micro-trenches 88 are provided on the lateral surfaces of the metal molded article 100 while coming into contact with the pores of the anodized film 10.

The direction of the metal molded article 100 may be distinguished since the first body region 100a is provided with the micro-trenches 88 and the second body region 100b is not provided with the micro-trenches 88. The metal molded article 100 may have a total thickness dimension H in a range of 100 um or more and 300 um or less in manufacturing. Due to this small size, it is not easy to distinguish between the first surface (front side) and the second surface (back side) of the metal molded article 100 with the naked eye alone. However, the first surface (front side) and the second surface (back side) of the metal molded article 100 may be distinguished since the first body region 100a is provided with the micro-trenches 88 and the second body region 100b is not provided with the micro-trenches 88. For example, the first body region 100a with the micro-trenches 88 provided may be determined as the first surface (front side) of the metal molded article 100, and the second body region 100a with no the micro-trenches 88 provided may be determined as the second surface (back side) of the metal molded article 100.

For the metal molded article 100 to be used in an inspection device 1, a plurality of the metal molded articles 100 is required to be inserted into a guide plate GP1 and a guide plate GP2. In particular, as will be described later, since the metal molded article 100 has the second connection portion 120 with the protrusion 188 protruded on one side, the metal molded article 100 is required to be inserted into the through-hole by distinguishing between the direction of the first surface (front side) and the second surface (back side). In a still yet further preferred embodiment of the present disclosure, the direction of the first surface (front side) and the second surface (back side) of the metal molded article 100 may be distinguished since the first body region 100a is provided with the micro-trenches 88, and the second body region 100b is not provided with the micro-trenches 88. Through this, when the metal molded article 100 with different first surface (front side) and second surface (back side) is inserted into the through-holes of the guide plate GP1 and guide plate GP2, incorrect insertion may be prevented.

The micro-trenches 88 are not formed on the first surface (front side) and second surface (back side) of the metal molded article 100.

The micro-trenches 88 have the effect of increasing the surface area on the lateral surfaces of the metal molded article 100. Through the configuration of the micro-trenches 88 formed on the lateral surfaces of the metal molded article 100, heat generated in the metal molded article 100 may be quickly dissipated. Thus, it is possible to suppress the temperature increase of the metal molded article 100.

The metal molded article 100 may be formed by stacking a plurality of metal layers in the thickness direction (±z direction) of the metal molded article 100. The plurality of metal layers includes first metal layers 101, a second metal layer 102, and a third metal layer 103.

The first metal layers 101 are made from metal with relatively high wear resistance compared to the second metal layer 102. The first metal layers 101 may preferably be formed by any metal selected from the group consisting of rhodium (Rd), platinum (Pt), iridium (Ir), palladium (Pd), nickel (Ni), manganese (Mn), tungsten (W), phosphorus (Ph) or alloys thereof, or palladium-cobalt (PdCo) alloy, palladium-nickel (PdNi) alloy, nickel-phosphorus (NiPh) alloy, nickel-manganese (NiMn), nickel-cobalt (NiCo), or nickel-tungsten (NiW) alloy. The second metal layer 102 is made of metal with relatively high electrical conductivity compared to the first metal layer 101. The second metal layer 102 may preferably be made of any metal selected from the group consisting of copper (Cu), silver (Ag), gold (Au), or alloys thereof but is not limited thereto.

The first body region 100a may be formed of the first metal layers 101 and the second metal layer 102. The first metal layers 101 are provided in the thickness direction (±z direction) of the metal molded article 100, and the second metal layer 102 is provided between the two first metal layers 101. For example, the metal molded article 100 is provided by alternately stacking the first metal layers 101, the second metal layer 102, and the first metal layers 101 in the thickness direction (±z direction) in that order, and the number of stacked layers may be three or more.

The second body region 100b may be formed of the third metal layer 103. The third metal layer 103 may be formed of the same metal as the first metal layers 101 or the second metal layer 102 constituting the first body region 100b, or may be formed of a different metal. In a still yet further preferred embodiment of the present disclosure, the protrusion 188 is formed in the second body region 100b, so the second body region 100b is made of metal with high wear resistance and may be made of metal selected from the first metal layers 101.

The metal molded article 100 may be an electrically conductive contact pin connected to the inspection target 400 to inspect the electrical characteristics of the inspection target 400. For this, the metal molded article 100 is connected to a first connection portion 110, a second connection portion 120, an elastic portion 150 connected to the first connection portion 110 and/or the second connection portion 120 and elastically deformable along the longitudinal direction (±y direction). A first contact point of the first connection portion 110 is connected to a circuit wiring portion, and the second connection portion 120 is connected to the inspection target 400. The elastic portion 130 allows the first connection portion 110 and the second connection portion 120 to be elastically displaced in the longitudinal direction of the metal molded article 100. The elastic portion 130 allows the first connection portion 110 to be elastically displaced relative to the second connection portion 120 in the longitudinal direction (±y direction).

The first connection portion 110, the second connection portion 120, and the elastic portion 150 are provided as integrated. The first connection portion 110, the second connection portion 120, and the elastic portion 150 are manufactured all at once using a plating process. The conventional pogo-type electrically conductive contact pins are provided by separately manufacturing a barrel and pin portion and then assembling or combining the two. Meanwhile, the metal molded article 100 in a still yet further preferred embodiment of the present disclosure is provided as an integrated piece by manufacturing the first connection portion 110, the second connection portion 120, and the elastic portion 150 all at once using a plating process. Thus. there is a difference in configuration between the conventional pin and the pin of the present disclosure. In addition, the conventional pogo-type electrically conductive contact pin does not have a spring formed in a spiral shape. Meanwhile, the elastic portion of the metal molded article 100 in a still yet further preferred embodiment of the present disclosure is formed in a leaf spring shape. Thus, there is a difference in configuration between the conventional pin and the pin of the present disclosure.

The elastic portion 130 is formed by alternately connecting a plurality of straight portions 130a and a plurality of curved portions 130b. The straight portions 130a connect the curved portions 130b adjacent to the left and right, and the curved portions 130b connect the straight portions 130a adjacent to the top and bottom. The curved portions 130b are provided in an arc shape.

The straight portions 130a are placed at the center of the elastic portion 130, and the curved portions 130b are placed outside the elastic portion 130. The straight portions 130a are provided parallel to the width direction to make it easier to deform the curved portions 130b depending on contact pressure.

The elastic portion 130 includes an upper elastic portion 131 connected to the first connection portion 110 and a lower elastic portion 133 connected to the second connection portion 120.

An inelastic portion 140 is formed between the upper elastic portion 131 and the lower elastic portion 133. The inelastic portion 140 is connected to the upper elastic portion 131, and the lower elastic portion 133 is connected to the outer wall portion 150.

The elastic portion 130 has the same cross-sectional shape in the thickness direction (±Z direction) of the metal molded article 100 across all thickness cross-sections. In addition, the elastic portion 130 has the same overall thickness. The elastic portion 130 is formed by taking a flat plate with an actual width t repeatedly being bent in an S shape. The actual width t of the flat plate is constant throughout. The flat plate has a ratio of actual width to thickness in a range of 1:5 or more and 1:30 or less.

Before the metal molded article 100 is used to inspect the inspection target 400, the first connection portion 110 comes in contact with the circuit wiring portion, the upper elastic portion 131 may be contracted and deformed in the longitudinal direction of the metal molded article 100, and the second connection portion 120 does not come in contact with the inspection target 400. In the process of inspecting the inspection target 400 with the metal molded article 100, the second connection portion 120 may come into contact with the inspection target 400, and the lower elastic portion 133 may be contracted and deformed.

One end of the first connection portion 110 is a free end, and the other end is connected to the upper elastic portion 131, allowing elastic perpendicular movement by contact pressure. One end of the second connection portion 120 is a free end, and the other end is connected to the lower elastic portion 133, allowing elastic perpendicular movement by contact pressure.

The upper elastic portion 131 requires enough contraction for each of the first connection portions 110 of the plurality of metal molded article 100 to come into contact with the circuit wiring portions 300 in a stable way. Meanwhile, the lower elastic portion 133 requires enough contraction for each of the second connection portions 120 of the plurality of metal molded articles 100 to come into contact with inspection targets 400 in a stable way. Therefore, the spring coefficient of the upper elastic portion 131 and the spring coefficient of the lower elastic portion 133 are different. For example, the length of the upper elastic portion 131 and the length of the lower elastic portion 133 are different. In addition, the length of the lower elastic portion 133 in the longitudinal direction may be longer than that of the upper elastic portion 131 in the longitudinal direction.

One end of the upper elastic portion 131 is connected to the first connection portion 110, and the other end is connected to the inelastic portion 140. One end of the lower elastic portion 133 is connected to the second connection portion 120, and the other end is connected to the inelastic portion 140. The elastic portion 130 connected to the inelastic portion 140 is the curved portion 130b of the elastic portion 130. Through this, the upper elastic portion 131 and the lower elastic portion 133 maintain elasticity relative to the inelastic portion 140.

The upper elastic portion 131 is provided above the inelastic portion 140. The lower elastic portion 133 is provided below the inelastic portion 140. By the inelastic portion 140, the area where the upper elastic portion 131 is provided and the area where the lower elastic portion 133 is provided are distinguished from each other. The upper elastic portion 131 and the lower elastic portion 133 are contracted or stretched relative to the inelastic portion 140. Due to the configuration of the inelastic portion 140 interposed between the upper elastic portion 131 and the lower elastic portion 133, the mechanical rigidity of the metal molded article 100 may be secured even when the length of the metal molded article 100 is increased.

The inelastic portion 140 includes a hollow portion 145. The hollow portion 145 is formed by penetrating the inelastic portion 140 in the thickness direction (±z direction). A plurality of the hollow portions 145 may be provided spaced apart from each other. Due to the configuration of the hollow portion 145, the surface area of the inelastic portion 140 may be increased. Through this, heat generated in the inelastic portion 140 may be quickly dissipated, thereby suppressing the temperature rise of the inelastic portion 140. The shape of the hollow portion 145 is illustrated as a triangle but is not limited thereto.

The metal molded article 100 induces an outer wall portion 150 provided outside the elastic portion 130 and arranged to extend in the longitudinal direction of the metal molded article 100 to allow the elastic portion 130 to contract and extend in the longitudinal direction of the metal molded article 100 and to prevent the elastic portion 130 from buckling by the elastic portion 130 being bent or curved sideways direction.

The outer wall portion 150 includes an upper outer wall portion 151 provided outside the upper elastic portion 131 and a lower outer wall portion 153 provided outside the lower elastic portion 133.

As the first connection portion 110 descends perpendicularly in the space surrounded by the upper outer wall portion 151, an additional contact point between the first connection portion 110 and the upper outer wall portion 151 is formed. As the second contact portion 120 ascends perpendicularly in the space surrounded by the lower outer wall portion 153, the second contact point is involved in a wiping operation. In the process of inspecting the inspection target 400 with the metal molded article 100, the metal molded article 100 maintains a perpendicular state, and the second connection portion 120 maintains contact pressure on the inspection target 400 and is involved in a wiping operation on the inspection target 400 while being tilted.

The upper outer wall portion 151 and the lower outer wall portion 153 are formed along the longitudinal direction of the metal molded article 100. The upper outer wall portion 151 and the lower outer wall portion 153 are integrally connected to the inelastic portion 140. In addition, the upper elastic portion 131 and the lower elastic portion 133 are integrally connected to the inelastic portion 140, and the metal molded article 100 is made of one body as a whole.

For the metal molded article 100 to be fastened to guide plates GP1 and GP2, a latching portion 152 is provided on the outer wall of the upper outer wall portion 151. That is, the upper outer wall portion 151 includes the latching portion 152 so that the metal molded article 100 is prevented from being separated from the guide plates GP1 and GP2. The latching portion 152 may be configured to be caught by one or more of the guide plates GP1 and GP2. Preferably, the latching portion 152 may be configured to be caught by the upper guide plate GP1. In this case, the latching portion 152 includes an upper latching portion 152a caught by the first surface of the upper guide plate GP1 and a lower latching portion 152b caught by the second surface of the upper guide plate GP1. The metal molded article 100 is prevented from being separated from the upper guide plate GP1 by bringing the upper guide plate GP1 to be caught between the upper engaging portion 152a and the lower engaging portion 152b. On the other hand, unlike this, the latching portion 152 may be configured to include an upper latching portion 152a caught by the first surface of the lower guide plate GP2 and a lower latching portion 152b caught by the second surface of the lower guide plate GP2.

The upper outer wall portion 151 includes a first upper outer wall portion 151a provided on one side of the upper elastic portion 131 and a second upper outer wall portion 151b provided on the other side of the upper elastic portion 131. The first upper outer wall portion 151a and the second upper outer wall portion 151b are close to each other at both ends but are spaced apart from each other to form an upper opening 153a.

The lower outer wall portion 153 includes a first lower outer wall portion 153a provided on one side of the lower elastic portion 133 and a second lower outer wall portion 153b provided on the other side of the lower elastic portion 133. The first lower outer wall portion 153a and the second lower outer wall portion 153b are close to each other at both ends, but are spaced apart from each other to form a lower opening 153b.

The upper opening 153a and lower opening 153b function to prevent the first connection portion 110 and second connection portion 120 from excessively protruding out of the upper outer wall portion 151 and lower outer wall portion 153, respectively by the restoring force of the upper elastic portion 131 and the lower elastic portion 133.

The first upper outer wall portion 151a has a first door portion 154a extending towards the upper opening 153a. The second upper outer wall portion 151b is provided with a second door portion 154b extending towards the upper opening 153a. The space where the first door portion 154a and the second door portion 154b face each other and are spaced apart becomes the upper opening 153a. The opening width of the upper opening 153a is smaller than the left and right lengths of the straight portion 130a of the upper elastic portion 131.

The first connection portion 110 is connected to the straight portion 130a of the upper elastic portion 131 and has a rod shape elongated in the longitudinal direction of the metal molded article 100. The first connection portion 110 may pass in the perpendicular direction through the upper opening 153a formed by the first upper outer wall portion 151a and the second upper outer wall portion 151b. In addition, as the left and right lengths of the straight portion 130a of the upper elastic portion 131 are formed to be greater than the width of the upper opening 153a, the straight portion 130a of the upper elastic portion 131 does not pass through the upper opening 153a. Through this, the upward stroke of the first connection portion 110 is limited.

The upper outer wall portion 151 and the lower outer wall portion 153 are close to each other at both ends but are spaced apart from each other to form an upper opening 153a, through which the first connection portion 110 may pass through in the perpendicular direction. When the first connection portion 110 descends perpendicularly in the space surrounded by the upper outer wall portion 151, the opening width of the upper opening 153a decreases and the first connection portion 110 comes into contact with the upper outer wall portion 151 to form an additional contact point.

The first upper outer wall portion 151a has a first extension portion 155a extending towards the inner space, and the second upper outer wall portion 151b has a second extension portion 155b extending towards the inner space.

More specifically, the first extension portion 155a is connected to the first door portion 154a. The first extension portion 155a has one end connected to the first door portion 154a, and its other end extends towards the inner space of the upper outer wall portion 151 to form a free end. A second extension portion 155b is connected to the second door portion 154b. The second extension portion 155b has one end connected to the second door portion 154b, and its other end extends towards the inner space of the upper outer wall portion 150 to form a free end.

The first connection portion 110 has a first protruding piece 110a extending towards the first extension portion 155a and a second protruding piece 110b extending towards the second extension portion 155b. When the first connection portion 110 is lowered by pressing force, the first protruding piece 110a and the second protruding piece 110b may come into contact with the first extension portion 155a and the second extension portion 155b, respectively.

When the first connection portion 110 is lowered, the first protruding piece 110a and the second protruding piece 110b may come into contact with the first extension portion 155a and the second extension portion 155b, respectively, to form an additional contact point.

With the inclined formation of the first extension portion 155a and the second extension portion 155b, when the first connection portion 110 is lowered, the first protruding piece 110a and the second protruding piece 110b compress the first extension portion 155a and the second extension portion 155b, respectively, thereby the space apart between the first door portion 154a and the second door portion 154b is reduced. In other words, as the first connection portion 110 descends, the first door portion 154a and the second door portion 154b are deformed to come closer to each other, thereby reducing the opening width of the upper opening 153a. In this way, when the first connection portion 110 descends perpendicularly in the space surrounded by the upper outer wall portion 151, the opening width of the upper opening 153a decreases, and the first connection portion 110 comes into contact with the upper outer wall portion 151 to form an additional contact point.

As the first connection portion 110 descends, the first protruding piece 110a and second protruding piece 110b primarily come into contact with the first extension portion 155a and second extension portion 155b, respectively to form an additional contact point. Due to the additional lowering, the first door portion 154a and second door portion 154b secondarily come into contact with the first connection portion 110 to form an additional contact point. Likewise, as the first connection portion 110 perpendicularly descends, an additional current path is formed between the first connection portion 110 and the upper outer wall portion 151. This additional current path is formed directly from the upper outer wall portion 151 to the first connection portion 110 without passing through the elastic portion 130. As the additional current path is formed, a more stable electrical connection is possible.

The opening width of the upper opening 153a decreases in proportion to the perpendicular downward distance of the first connection portion 110. In addition, even after the first door portion 154a and second door portion 154b come into contact with the first connection portion 110, when downward pressure is applied to the first connection portion 110, the friction between the first door portion 154a and the first connection part 110 and the friction between second door portion 154b and the first connection part 110 increase further. The increased friction prevents excessive lowering of the first connection portion 110. Through this, it is possible to prevent the elastic portion (more specifically, the upper elastic portion 131) from being excessively contracted and deformed.

The second connection portion 120 is connected to the lower elastic portion 133 at the top, and the other end of the second connection portion 120 passes through the lower opening 153b.

The second connection portion 120 has an inner body 121 connected to the lower elastic portion 133, an extension body 123 protruding to the outside of the lower outer wall portion 153, and a protrusion 188 provided at the end of the extension body 123.

The second connection portion 120 is repeatedly involved in raising and lowering operations. In this process, the left and right lengths of the lower surface of the inner body 121 are longer than the opening width of the lower opening 143b so that the inner body 121 is prevented from being separated from the outer wall portion 150.

A hollow portion 122 is formed in the inner body 121. The hollow portion 122 is formed by penetrating the inner body 121 in the thickness direction (±z direction). Due to the configuration of the hollow portion 122, the inner body 121 may be contracted and deformed by pressing force. In addition, as the inner body 121 is contracted and deformed, the wiping operation of the protrusion 188 is smoother.

The extension body 123 extends to the inner body 121, and at least a portion of the extension body 123 passes through the lower opening 153b and is located outside the lower outer wall portion 153.

A protrusion 188 is provided at one end of the extended body 123. The protrusion 188 is formed to have a thickness smaller than that of the extended body 123. In the second connection portion 120, a portion of the second body region 100b protrudes beyond the first body region 100a to form a protrusion 188. The protrusion 188 is a portion of the second body region 100b.

During the wiping operation of the protrusion 188, debris of the oxide film formed on the surface of the inspection target 400 is generated. The debris tends to grow continuously by being electrodeposited and clumped together. However, these debris are caught at the end of the extended body 123, which is the root of the protrusion 188, and are induced to fall naturally without growing any further. In this way, due to the configuration of the protrusion 188 formed at the end of the extension body 123 with a thickness smaller than that of the extension body 123, the debris of the oxide film generated during the wiping process is prevented from continuously growing.

According to the method of manufacturing the metal molded article 100 described later, it is possible to set the actual width t of the flat plate constituting the elastic portion 130 to 10 μm or less, more preferably 5 μm. Since it is possible to form the elastic portion 130 by configuring a flat plate with an actual width t of 5 μm in a bent shape, it becomes possible to reduce the overall width dimension W of the metal molded article 100. As a result, a narrow pitch response becomes possible. In addition, the overall thickness dimension H may be configured within the range of 100 μm or more and 300 μm or less. Accordingly, it is possible to shorten the length of the elastic portion 130 while preventing damage to the elastic portion 130. Even when the length of the elastic portion 130 is shortened, it is possible to have an appropriate contact pressure through the configuration of the flat plate. Furthermore, it is possible to increase the overall thickness dimension H compared to the actual width t of the flat plate constituting the elastic portion 130. Thus, resistance to the moment acting in the front and rear directions of the elastic portion 130 increases, and as a result, contact stability is improved.

It is possible to shorten the length of the elastic portion 130. Thus, the overall thickness dimension H and the overall length dimension L of the metal molded article 100 are in the range of 1:3 to 1:9. Preferably, the overall length dimension L of the metal molding 100 may be in the range of 300 μm or more and 3 mm or less, and more preferably in the range of 450 μm or more and 600 μm or less. In this way, it becomes possible to shorten the overall length dimension L of the metal molded article 100, making it easier to respond to high-frequency characteristics. As the elastic recovery time of the elastic portion 130 is shortened, the test time may also be shortened.

The overall thickness dimension H and the overall width dimension W of the metal molded article 100 are in the range of 1:1 to 1:5. Preferably, the overall thickness dimension H of the metal molded article 100 may be in the range of 100 μm to 300 μm, and the overall width dimension W of the metal molded article 100 may be in the range of 100 μm to 300 μm. In this way, it becomes possible to narrow the pitch by shortening the overall width dimension W of the metal molded article 100.

The overall thickness H and W of the metal molded article 100 may be formed to have substantially the same length. Thus, there is no need to join a plurality of metal molded articles 100 in the thickness direction so that the overall thickness dimension H and the overall width dimension W are substantially the same length. In addition, since it is possible to form the overall thickness dimension H and overall width dimension W of the metal molding 100 to be substantially the same length, resistance to the moment acting in the front and rear directions of the metal molded article 100 increases, and as a result, contact stability is improved. Furthermore, according to a configuration in which the overall thickness dimension H of the metal molded article 100 is 100 μm or more, and the overall thickness dimension H and overall width dimension W are in the range of 1:1 to 1:5, the overall durability and deformation stability of the metal molded article 100 are improved, thereby the stability of contact with external terminals 25 is improved. In addition, the overall thickness dimension H of the metal molded article 100 is formed to be 100 μm or more. Thus, the current carrying capacity may be improved.

The metal molded article 100 manufactured using a photoresist mold inevitably has a smaller overall thickness H compared to the overall width W. For example, the metal molded article 100 has an overall thickness dimension H of less than 40 μm and at the same time has an overall thickness dimension H and an overall width dimension W to be in the range of 1:2 to 1:10. Thus, resistance to the moment which deforms the electrical metal molded article 100 in the front and rear directions due to contact pressure is weak. To prevent problems caused by excessive deformation of the elastic portion on the front and back sides of the metal molded article 100, further housing is required to be considered on the front and back sides of the metal molded article 100. However, according to a still yet further preferred embodiment of the present disclosure, no additional housing construction is required.

### Method of Manufacturing Metal Molded Article (100)

Hereinafter, a method of manufacturing a metal molded article 100 according to a preferred embodiment of the present disclosure will be described.

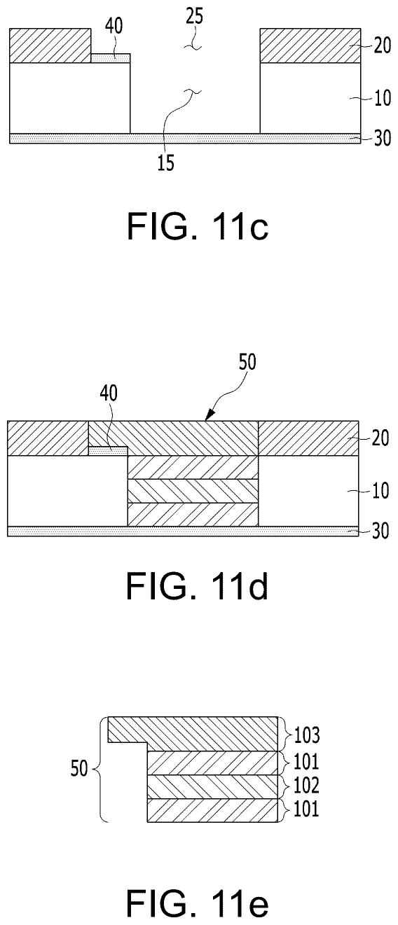

FIGS. 11a to 11e show views of a method of manufacturing a metal molded article 100 according to another preferred embodiment of the present disclosure.

The method of manufacturing a metal molded article 100 includes forming a lower seed layer 30 on a lower surface of the anodized film 10; forming a patternable material 20 on an upper surface of the anodized film 10; forming a second opening 25 to expose the upper surface of the anodized film 10 by patterning the patternable material 20; forming a first opening 15 by wet etching the anodized film 10 to expose the lower seed layer 30 using the second opening 25; forming a body metal layer 50 in the first opening 15 and the second opening 25 through plating: and extracting the body metal layer 40 by removing the lower seed layer 30, the patternable material 20, and the anodized film 10.

Referring to FIG. 11a, the forming of the lower seed layer 30 on the lower surface of the anodized film 10 will be described.

The anodized film 10 refers to a film formed by anodizing a base metal. A pore refers to a hole formed during the process of anodizing a metal to form an anodized film. For example, when the base metal is aluminum (Al) or an alloy thereof, and the base material is anodized, an anodized film of aluminum oxide (Al₂O₃) is formed on the surface of the base metal. However, the base metal is not limited thereto and includes Ta, Nb, Ti, Zr, Hf, Zn, W, and Sb, or alloys thereof. The anodized film formed as above is perpendicularly divided into a pore-free barrier layer and a pore-existing porous layer. When an anodized film 10 having the barrier layer and the porous layer is formed on the surface of the base metal, and the base metal is removed, only the anodized film 10 made of aluminum oxide (Al₂O₃) remains. The formed anodized film 10 may have a structure in which pores penetrate the film from top to bottom by removing the barrier layer formed during the anodization. Alternatively, the formed anodized film 10 may have a structure in which the barrier layer formed during the anodization remains intact and seals one end of the upper and lower ends of the pores.

Since the metal molded article 100 according to a further preferred embodiment of the present disclosure is manufactured using the anodized film 10, it is possible to effectively realize precise and fine shapes that were previously limited to realize with a photoresist. In addition, in the case of using existing photoresists, as thick as 40 μm metal molded article may be manufactured. However, when the anodized film 10 is used, it is possible to manufacture a metal molded article 100 with a thickness of 100 μm or more and 260 μm or less. Therefore, it is possible to manufacture a sufficiently thick mold by using the photoresist and the anodized film together as a mold. Meanwhile, the thickness of the anodized film 10 may vary depending on the manufacturing process but is basically formed thicker than a single film of photoresist.

The lower seed layer 30 is provided on the lower surface of the anodized film 10. The lower seed layer 30 may be formed by depositing a metal material. The lower seed layer 30 is used when forming a body metal layer 50, particularly the first body region 100a, using a plating process. The lower seed layer 30 may be formed on the entire lower surface of the anodized film 10.

An upper seed layer 40 is provided on the upper surface of the anodized film 10. The upper seed layer 40 may be formed by depositing a metal material. The upper seed layer 40 is used when forming a body metal layer 50, particularly the second body region 100b, using a plating process. The upper seed layer 40 may be formed on the upper surface of the anodized film 10.

The lower seed layer 30 and the upper seed layer 40 are removed after forming the body metal layer 50. Accordingly, the lower seed layer 30 and the upper seed layer 30 are preferably made from a different metal material than the body metal layer 50.

Next, referring to FIG. 11b, the forming of patternable material 20 on upper surface of the anodized film 10 and the forming of a second opening 25 to expose the upper surface of the anodized film 10 by patterning the patternable material 20 will be described.

A patternable material 20 is formed on the upper surface of the anodized film 10 with the upper seed layer 40 formed on the film. The patternable material 20 is made from a material capable of being subjected to exposure and development processes, and the patternable material includes a photoresist.

The patternable material 20 formed on the upper surface of the anodized film 10 is patterned to form a second opening 25 so that the upper surface of the anodized film 10 is exposed. This leads the second mold of the patternable material 20 to be provided on the upper surface of the anodized film 10.

Then, referring to FIG. 11c, the forming of a first opening 15 by wet etching the anodized film 10 to expose the lower seed layer 30 using the second opening 25 will be described.

To perform wet etching, the upper seed layer 40 provided on the upper surface of the anodized film 10 and the patterned patternable material 20 are used as a mask, and a solution that reacts only to the anodized film 10 is used. As the anodized film 10 is selectively removed, a first opening 15 is formed in the anodized film 10. Through this, a first mold of the anodized film 10 with the first opening 15 formed therein is formed. That is, a second mold of the patternable material 20 is provided on the upper surface of the first mold of the anodized film 10, and the first opening 15 and the second opening 25 communicate with each other to form one space.

The patterned patternable material 20 not only functions as a mold for plating but also as a mask for forming the first opening 15. Accordingly, in the area where the patternable material 20 functions as a mask, the first opening 15 and the second opening 25 are formed perpendicular to the thickness direction (±z direction). Therefore, when the first opening 15 is formed in the mold of the anodized film 10, the second opening 25 is formed in the mold of the patternable material 20, and then the mold of the anodized film 10 and the mold of the patternable material 20 are combined with each other. For reference, the mold of the anodized film 10 is provided with the first opening 15, and the mold of the patternable material 20 is provided with the second opening 25 in the combination process. With the combination, misalignment problems are prevented from occurring.

Afterward, referring to FIG. 11d, the forming of a body metal layer 50 in the first opening 15 and the second opening 25 through plating will be described.

A metal layer formation is carried out in the first opening 15 and the second opening 25 through plating to form a body metal layer 50.

A first plating process is performed in the first opening 15 using the lower seed layer 30. The plating layer formed in the first opening 15 constitutes the first body region 100a. The first plating process may be a multi-layer plating process involving first metal layers 101 and a second metal layer 102. Accordingly, the first body region 100a may be made from multiple metal layers including the first metal layers 101 and the second metal layer 102. Since the first body region 100a is a region manufactured using the first mold of the anodized film 10, micro-trenches 88 are formed on the lateral surfaces of the first body region 100a.

Next, a second plating process is performed in the second opening 25 using the already plated metal layer and the upper seed layer 40. The plating layer formed in the second opening 25 constitutes the second body region 100b. Since the second body region 100b is a region manufactured using the second mold of the patternable material 20, micro-trenches 88 are not formed on the lateral surfaces of the second body region 100b.

The second plating process may be made of a single metal layer. The second plating process may be a single-layer plating process involving a third metal layer 103. The material of the third metal layer 103 may vary depending on the function of the second body region 100b. For example, when the second body area 100b requires wear resistance and mechanical rigidity, the third metal layer 103 may be formed of one of the metals selected to form the first metal layers 101. Alternatively, when high electrical conductivity is required, the third metal layer 103 may be formed of one of the metals selected to form the second metal layer 102. The third metal layer 103 may be formed of the same metal as the first metal layers 101 or the second metal layer 102 constituting the first body region 100b, or may be formed of a different metal. In a yet further preferred embodiment of the present disclosure, the protrusion 188 is formed in the second body region 100b, so the second body region 100b is formed of a metal with high wear resistance and may be formed of one of the metals selected to form the first metal layers 101.

The upper seed layer 40 is used to improve the quality of a plating layer formed on the upper surface thereof and to shorten the plating time. Without the upper seed layer 40, it is difficult to make the length of a protrusion 188 long, and a polishing process is unnecessarily required. Therefore, with the introduction of the upper seed layer 40, it is possible to precisely form the shape of the protrusion 188 and prevent unnecessary polishing processes.

The first body region 100a is formed by plating metal layers in the first opening 15 the anodized film 10. The second body region 100b is formed by plating a metal layer in the second opening 25 the patternable material 20. The first body region 100a and the second body region 100b are formed as an integrated body being continuous to each other in the thickness direction of the metal molded article 100.

Afterward, referring to FIG. 11e, the extracting of the body metal layer 40 by removing the lower seed layer 30, the patternable material 20, and the anodized film 10 will be described.

The patternable material 20 is removed using a material that only reacts with the patternable material 20. In addition, the lower seed layer 30 and the upper seed layer 40 are removed using a material that reacts only to the lower seed layer 30 and the upper seed layer 40. In addition, the anodized film 10 is removed using a material that only reacts with the anodized oxide film 10. In this way, only the metal-plated body metal layer 40 is extracted.

When manufacturing the metal molded article 100 using only the photoresist, it is difficult to make the mold height sufficiently high using only a single layer of the photoresist. As a result, the thickness of the metal molded article 100 cannot be sufficient. Considering electrical conductivity, resilience, and brittle fracture, the metal molded article 100 needs to be manufactured to have a predetermined thickness or more. To increase the thickness of the metal molded article 100, a configuration of a multi-layered photoresist may be considered. However, in this case, each layer of the photoresist has fine steps, so the lateral sides of the metal molded article 100 are not formed perpendicularly, and a slightly stepped area remains. In addition, when the photoresist is multi-layered, it is difficult to precisely reproduce the shape of the metal molded article 100 with a dimension range of several tens of μm or less.

On the other hand, when the metal molded article 100 is manufactured using the anodized film 10 as a mold, it is advantageous in that it is possible to manufacture the metal molded article 100 having its lateral surfaces positioned in a perpendicular way. However, since the anodized film 10 is manufactured through an anodization process, it takes a lot of time to make its height sufficiently thick.

Therefore, when the anodized film 10 and a patternable material are used in combination as a mold for electroplating, it is possible not only to manufacture a metal molded article 100 with the lateral surfaces thereof positioned in a perpendicular way and excellent shape precision but also to make up for the insufficient height of the anodized film 10 with the patternable material. In addition, when only the anodized film 10 is used, it may be difficult to manufacture the metal molded article 100 having a three-dimensional shape (for example, protrusion 188) in the height direction. Meanwhile, by combining the mold of the anodized film 10 and the mold of the patternable material 20, it becomes easy to manufacture a metal molded article 100 having a three-dimensional shape in the height direction.

The mold of the patternable material 20, is provided on the upper surface of the mold of the anodized film 10. According to the configuration that the mold of the patternable material 20, is provided on the upper surface of the mold of the anodized film 10, the crack removal plating process is completed before the mold of the patternable material 20 protects the mold of the anodized film 10 during the planarization process (CMP). In that respect, it is possible to have an additional effect of preventing cracks from occurring.

The mold of the anodized film 10 may be used to manufacture the basic shape of the metal molded article 100. The mold of the patternable material 20 may be used to manufacture complex three-dimensional shapes other than the basic shape or may be used to increase the height of the basic shape.

### Inspection Device (1)

Herein below, an inspection device 1 according to a preferred embodiment of the present disclosure will first be described.

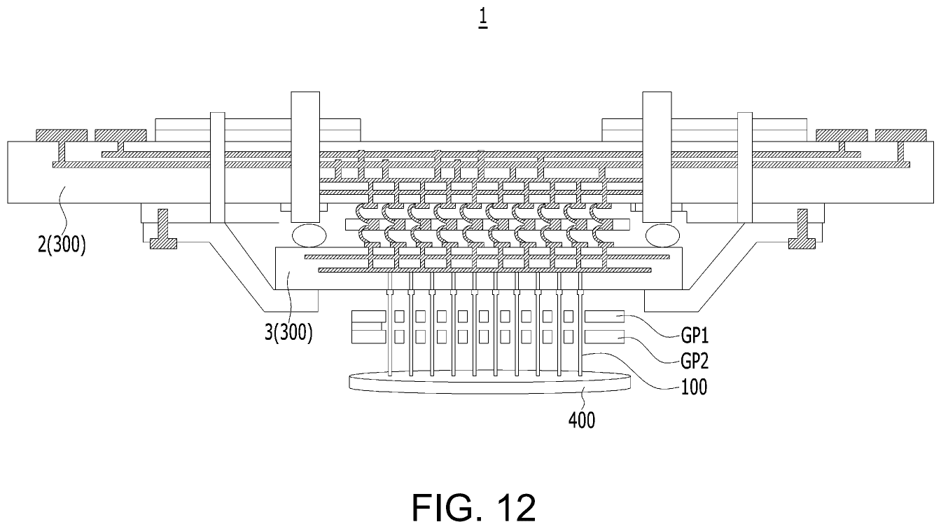

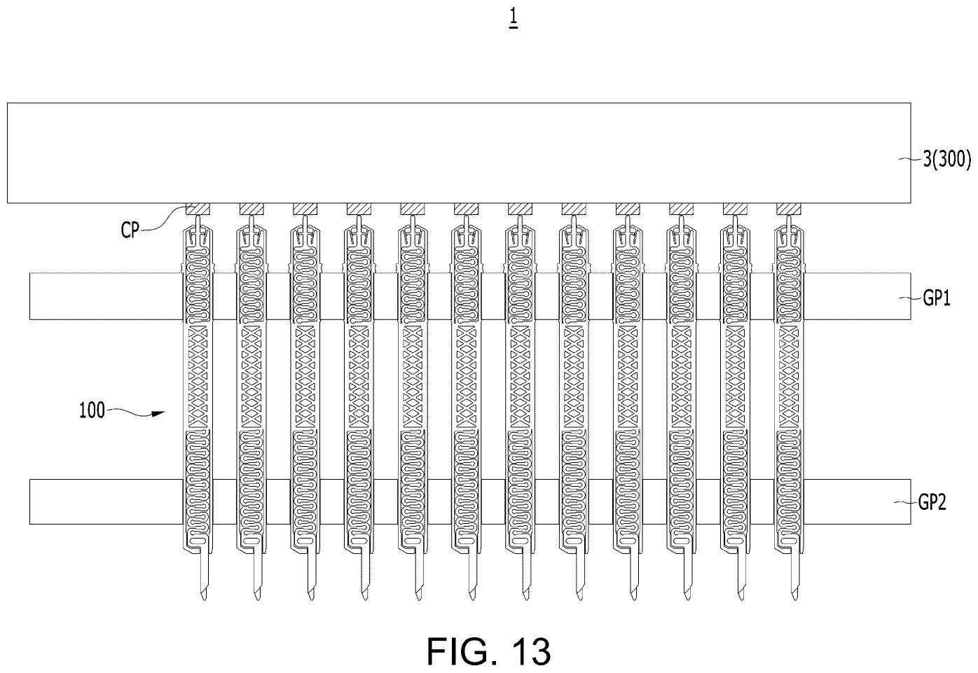

FIG. 12 shows a view of an inspection device equipped with metal molded articles according to another preferred embodiment of the present disclosure, and FIG. 13 shows an enlarged view of the part of FIG. 12.

The inspection device 1 may be an inspection device used in the semiconductor manufacturing process. For example, the inspection device may be a probe card or a test socket. Metal molded articles 100 may be electrically conductive contact pins provided on the probe card to inspect a semiconductor chip. The metal molded articles 100 may be electrically conductive contact pins to inspect a semiconductor package, being provided in the test socket to inspect a packaged semiconductor package. The inspection device 1 to which the metal molded articles 100 according to a further preferred embodiment of the present disclosure is applicable is not limited thereto. The inspection device 1 includes any inspection device to which electricity is applied to check whether an inspection target 400 is defective.

The inspection target 400 of the inspection device 1 may include a semiconductor device. a memory chip, a microprocessor chip, a logic chip, and a light emitting device, or a combination thereof. For example, the inspection target 400 includes logic LSIs (for example, ASICs, FPGAs. and ASSPs), microprocessors (for example, CPUs and GPUs), memory (for example, DRAM, hybrid memory cube (HMC)), magnetic RAM (MRAM), phase-change memory (PCM), resistive RAM (ReRAM), ferroelectric RAM (FeRAM), and flash memory (for example, NAND flash), semiconductor light emitting devices (for example, LED, mini LED, and micro LED), power devices, analog ICs (for example, DC-AC converters and insulated gate bipolar transistors (IGBTs)), MEMS (for example, acceleration sensors, pressure sensors, vibrators, and gyroscope sensors), wireless devices (for example, GPS, FM, NFC, RFEM, MMIC, and WLAN), discrete devices, BSI, CIS, camera module, CMOS, passive devices, GAW filters, RF filters, RF IPD, APE, and BB.

The inspection device 1 includes metal molded articles 100, a guide plate GP1 and a guide plate GP2 into which the metal molded articles 100 are inserted and installed, and circuit wiring portions 300 that are electrically connected to one side of the metal molded articles 100. Herein, first connection portions 110 of the metal molded articles 100 are connected to the circuit wiring portions 300. The second connection portions 120 of the metal molded articles 100 are connected to the inspection target 400. The metal molded articles 100 include elastic portions 130 that allow the first connection portions 110 to be elastically displaced relative to the second connection portions 120 in the longitudinal direction.

FIGS. 12 and 13 show diagrams illustrating the case where the inspection device 1 is the probe card. The inspection device 1 is made from probe heads 4 and the circuit wiring portions 300. The circuit wiring portions 300 include space converters 3 in contact with one end of the metal molded articles 100 and substrate portions 2 to which the space converters 3 are electrically connected.

The guide plate GP1 and the guide plate GP2 include an upper guide plate GP1 and a lower guide plate GP2 arranged to be spaced apart from each other. The metal molded articles 100 are installed by passing through the respective through-holes of the upper guide plate GP1 and the lower guide plate GP2. At this time, the metal molded articles 100 are fixed to the upper guide plate GP1 by the latching portions 152 provided on the upper outer wall portions 151. The first connection portions 110 of the metal molded articles 100 are connected to the pads CP of the space converters ST, 3. The second connection portions 120 of the metal molded articles 100 are connected to the inspection target 400 (for example, semiconductor wafer W).

When the metal molded articles 100 are installed by inserting them into the guide plate GP1 and the guide plate GP2, the direction of the metal molded articles 100 may be easily distinguished since the first body regions 100a are provided with the micro-trenches 88 and the second body regions 100b are not provided with the micro-trenches 88. Therefore, a plurality of the metal molded articles 100 is inserted into the guide plate GP1 and the guide plate GP2 in the same direction without error.

As described above, the present disclosure has been described with reference to preferred embodiments. However, those skilled in the art may implement the present disclosure by various modifications or variations without departing from the spirit and scope of the present disclosure as set forth in the patent claims below.

### EXPLANATION OF SYMBOLS

100: Metal molded article
110: First connection portion
120: Second connection portion
130: Elastic portion
140: Inelastic portion
150: Outer wall portion

1. A metal molded article having an overall length dimension in the longitudinal direction, an overall thickness dimension in the thickness direction perpendicular to the longitudinal direction, and an overall width dimension in the width direction perpendicular to the longitudinal direction,
wherein the metal molded article is divided into a first body region and a second body region in the thickness direction,
wherein the lateral surfaces of the first body region are provided with multiple micro-trenches that are grooves formed to be elongated in the thickness direction and arranged side by side all over the entire lateral surfaces of the first body region,
wherein the lateral surfaces of the second body region are not provided with these micro-trenches.

2. The metal molded article of claim 1, comprising:
a first surface;
a second surface opposite to the first surface, and
a lateral surface which is a surface connecting the first surface and the second surface to each other,
wherein the micro-trenches are not formed on the first surface and the second surface.

3. The metal molded article of claim 1, wherein the micro-trenches have a depth of 20 nm or more and 1 μm or less.

4. The metal molded article of claim 1, wherein a portion of the second body region has a protrusion that protrudes beyond the first body region,
the second body region, excluding the protrusion, has the same shape as the first body region.

5. The metal molded article of claim 1, wherein the first body region has a thickness greater than that of the second body region.

6. The metal molded article of claim 1, wherein the metal molded article is an electrically conductive contact pin connected to an inspection target to inspect the electrical characteristics of the inspection target.

7. The metal molded article of claim 1, comprising:
a first connection portion connected to a circuit wiring portion;
a second connection portion connected to an inspection target; and
an elastic portion that allows the first connection portion to be elastically displaced relative to the second connection portion in the longitudinal direction, and
wherein the second connection portion comprising a protrusion formed such that a portion of the second body region protrudes beyond the first body region.

8. The metal molded article of claim 7, comprising an outer wall portion provided outside the elastic portion and arranged to extend in the longitudinal direction of the metal molded article to allow the elastic portion to contract and extend in the longitudinal direction of the metal molded article and to prevent the elastic portion from buckling while the elastic portion contracts.

9. The metal molded article of claim 1, comprising:
a first connection portion connected to the circuit wiring portion;
a second connection portion connected to an inspection target;
an upper elastic portion connected to the first connection portion;
a lower elastic portion connected to the second connection portion; and
an inelastic portion connected to the upper elastic portion and the lower elastic portion, and interposed between the upper elastic portion and the lower elastic portion, and
the second connection portion comprising a protrusion formed such that a portion of the second body region protrudes beyond the first body region.

10. The metal molded article of claim 9, comprising:
an upper outer wall portion provided outside the upper elastic portion; and
a lower outer wall portion provided outside the lower elastic portion.

11. The metal molded article of claim 10, wherein the upper outer wall portion comprises a latching portion that protrudes to prevent the metal molded article from being separated from a guide plate.

12. An inspection device, comprising:
a metal molded article;
a guide plate into which the metal molded article is inserted and installed; and
a circuit wiring portion electrically connected to one side of the metal molded article, and
wherein the metal molded article comprises:
a first body portion provided with multiple micro-trenches that are grooves formed to be elongated in the thickness direction, and arranged side by side all over the entire lateral surfaces of the first body region; and
a second body portion formed to be continuous to the first body region in the thickness direction and provided with no micro-trenches on lateral surfaces thereof.

13. The inspection device of claim 12, wherein the metal molded article comprises:
a first connection portion connected to the circuit wiring portion;
a second connection portion connected to an inspection target; and
an elastic portion that allows the first connection portion to be elastically displaced relative to the second connection portion in the longitudinal direction, and
wherein the second connection portion comprising a protrusion formed such that a portion of the second body region protrudes beyond the first body region.

14. A method of manufacturing a metal molded article, the method comprising:
forming a lower seed layer on a lower surface of an anodized film;
forming a patternable material film on an upper surface of the anodized film;
forming a second opening to expose the upper surface of the anodized film by patterning the patternable material film;
forming a first opening by wet-etching the anodized film to expose the lower seed layer through the second opening;
forming a body metal layer in the first opening and the second opening through plating; and
extracting the body metal layer by removing the lower seed layer, the patternable material film, and the anodized film.

15. The method of claim 14, wherein the patternable material film is a photoresist.

16. The method of claim 14, further comprising forming of an upper seed layer on the upper surface of the anodized film before forming the first opening.
